(19) United States
(12) Patent Application Publication
(10) Pub. No.: US 2004/0257102 A1
(43) Pub. Date: Dec. 23, 2004

(54) Secure content protection for board connections

(76) Inventors: Hong W. Wong, Portland, OR (US); Bruce W. Maynard, Beaverton, OR (US); Truong Phan, Hillsboro, OR (US); Khanh Q. Tran, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/600,188

(22) Filed: Jun. 20, 2003

(51) Int. Cl. G01R 31/02

(52) U.S. Cl. 324/764

(57) ABSTRACT

In some embodiments, a controller detects a board coupling condition and performs a shutdown in response to the board coupling condition. Other embodiments are described and claimed.

### TECHNICAL FIELD

The inventions generally relate to secure content protection.

### BACKGROUND

Multimedia convergence consumer products typically provide all components on a baseboard in order to receive and process a content signal. However, such boards are typically proprietary and require a different board and design for each different convergence consumer product and for different geographies.

In some products such as new multimedia convergence consumer products (for example, Super Set-top-box and Home Server products) an important goal is to maintain content protection from the receiving end of the content to the attached devices. The receiving end may include, for example, tuner devices or content received via the Internet. The attached devices may include, for example, devices on a Local Access Network (LAN), a display, a television set, or a monitor. System designs can include different levels of content protection (CP). Content protection of external devices such as display with a digital interface can be performed, for example, using Digital Transmission Contention Protection (DTCP) or High-bandwidth Digital Content Protection (HDCP).

Various schemes have been contemplated for performing content protection. Such schemes can include a detection implementation where the system is disabled if the chassis case has been tampered with. Another scheme that may be used is encrypting content as it passes through a readily accessible bus (for example, a PCI bus with a connector) where a hacker could gain access to the contents with bus probing devices. Another scheme is to encrypt the content in the hard drive.

Another scheme is to marry the hard drive to a specific platform so that the content cannot be shared or copied easily. There are several drawbacks to each of these schemes, including significant additional cost to the system either due to the scheme itself and/or because of the proprietary nature of the platform. Very often, the schemes mentioned above (and other schemes not mentioned above such as smart card) are implemented on the same platform to achieve a comprehensive content protection system.

### BRIEF DESCRIPTION OF THE DRAWINGS

The inventions will be understood more fully from the detailed description given below and from the accompanying drawings of some embodiments of the inventions which, however, should not be taken to limit the inventions to the specific embodiments described, but are for explanation and understanding only.

FIG. 1 is a block diagram representation of some embodiments of the inventions.

FIG. 2 is a flow diagram of operation of some embodiments of the inventions.

FIG. 3 is a block diagram representation of some embodiments of the inventions.

### DETAILED DESCRIPTION

Some embodiments of the inventions relate to secure content protection of signals or information. Some embodiments relate to multimedia convergence consumer products. Convergence consumer products are an emerging market segment without many products of this type available in the market. Some of these products can include set-top-boxes, super set-top-boxes, or products such as TIVO or Ultimate TV devices (from Microsoft Corporation). These devices are targeted for a specific market segment, and hardware components such as the tuner, Conditional Access module (CA module) or Conditional Access System module (CAS module), micro-controller, processor and/or CPU, memory, video processing, graphics subsystem, video/graphics system, and/or other devices, for example, are all on the same board in a manner such that there is no need for an adapter. However, it is beneficial to design a platform according to some embodiments such that the platform may be re-used for different system manufacturers and for different geographies around the world (for example, in European, Far East and US markets). A modular design approach using add-in adapters would be very beneficial and highly cost effective. In some embodiments a modular design approach using adapters may be implemented.

In some embodiments secure content protection can be provided using a protection circuit extending among and between two boards such that an open circuit occurs if someone attempts to tamper with the system. This content protection can prevent probing of encrypted or decrypted multimedia content and detect disassembly of an adapter from a baseboard even if no AC power is being provided to the system (for example, because the system is unplugged). Booting of the system may be stopped in order to prevent any content such as multimedia content from being extracted from the system. In some embodiments an adapter (for example, a Conditional Access System adapter module) is married to a baseboard in a manner so as to prevent the adapter from being used on other “hacked up” systems.

In some embodiments probing of decrypted content is prevented. In some embodiments disassembly of an adapter is detected. This may be detected even if the system is unplugged and no AC power is provided to the system. The system booting operation may be stopped, and extraction of any content such as multimedia content from the system may be prevented. In some embodiments the adapter may be married to the motherboard to prevent the adapter from being used on other systems.

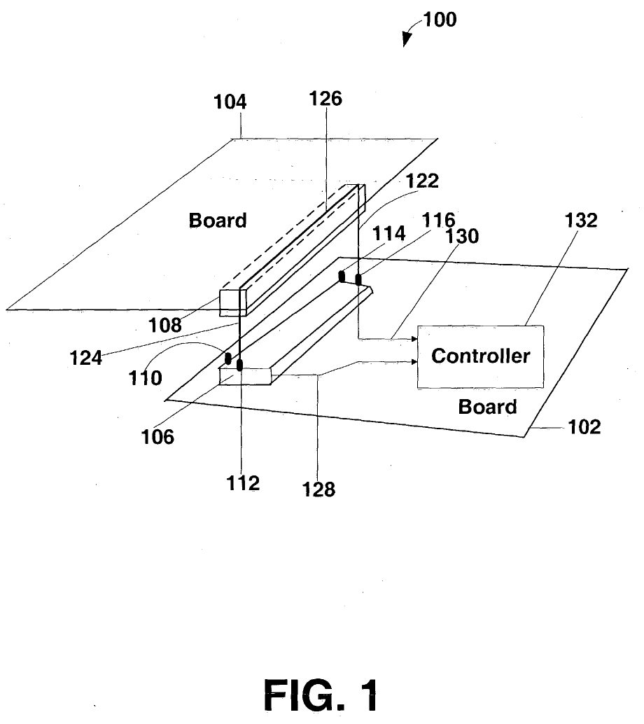

FIG. 1 illustrates a system 100 including a first board 102 and a second board 104. In some embodiments system 100 may be a consumer convergence system, a multimedia convergence system, and/or some other type of system. In some embodiments first board 102 may be a Printed Circuit Board (PCB), a motherboard, a baseboard, and/or some other type of board. In some embodiments second board 104 may be a device, a module, a component, hardware, a PCB, a card, an adapter board, an adapter card, an add-in board, an add-in card, some other type of board and/or some other type of card.

Board 102 includes a connector 106 that may be used to connect board 102 to something else (for example, another board or another connector). Board 104 includes a connector 108 that may be used to connect board 104 to something else (for example, another board or another connector).

Connector 106 may include one or more connector pins 110, 112, 114 and 116 that may be used to connect signal lines or traces or some other type of connection. Although four connector pins 110, 112, 114 and 116 are illustrated in FIG. 1 any number of connector pins may be used according to some embodiments, and connector pins may not be required for all embodiments. No connector pins are illustrated on connector 108 in FIG. 1. However, it is noted that connector 108 could have any number of connector pins similar to the connector pins 110, 112, 114 and 116 of connector 106. Alternatively, according to some embodiments connector 108 and/or connector 106 could include connection-mating receivers such that any other connector device or devices (such as connector pins 110, 112, 114 and 116) could connect with the receivers when the connectors 106 and 108 are mated.

When connectors 106 and 108 are mated in some fashion (for example, by pressing board 104 down toward board 102 until connectors 106 and 108 connect with each other) a closed circuit is formed along the lines 122, 124, 126, 128 and 130. Lines 122 and 124 are formed between connectors 106 and 108, line 126 is formed along, near, on or within connector 108, and lines 128 and 130 are formed along, near, on or within board 102. The end of lines 128 and 130 extend to a controller 132. Controller 132 can be a detector, and can include detection logic such as circuitry, firmware, software or some combination thereof. In some embodiments controller 132 can be used to detect if and/or when the connectors are connected or disconnected or whether the connectors have been connected or disconnected at some point, for example. In some embodiments controller 132 can detect a board coupling condition of the board 102 to the board 104. In some embodiments a board coupling condition can include a condition of the board 102 and 104 being connected or unconnected, or some other coupling condition between a board and another board.

In some embodiments the connection of lines 122, 124, 126, 128 and/or 130 and/or controller 132 can be referred to as a protection circuit (for example, a content protection circuit). In some embodiments the protection circuit can be used to provide protection for signals transmitted from one of the boards 102 and 104 to the other board and/or vice versa. In some embodiments the protection circuit can be a content protection circuit used to provide content protection for signals or information transmitted from one of the boards 102 and 104 to the other board and/or vice versa. According to some embodiments the protection and/or content protection can occur whether or not AC power is being supplied to either or both of the boards.

The arrows at the ends of lines 128 and 130 can be connected to a controller 132 and/or to some other detection logic. Controller 132 (and/or a detector and/or other detection logic) can be a chipset or other detection mechanism that is able to detect connection or lack of connection of the connectors 106 and 108 using the protection circuit or content protection circuit formed by lines 122, 124, 126, 128 and 130. The controller 132 that can detect the connection can be a device that remains operative when the system is in a sleep mode or some other mode where AC power is not supplied but some other power such as a system battery is providing backup power, for example. The controller 132 and/or other detection logic can be a device such as a controller, a detector, a detection mechanism, a chipset, and/or a portion of a chipset or some combination thereof, and can include inputs that are connected to lines 128 and 130 so that the device can determine, for example, if the protection circuit or content protection circuit including lines 122, 124, 126, 128 and 130 has or has had an open circuit. The controller 132 and/or other device can then perform a shutdown. The shutdown can include functions such as shutting down the system immediately, logging the event and then shutting down the system, provide an alert, set a register bit in permanent memory space (e.g., EEPROM), shut down the system and prevent further operation, prevent supply of power to one or more of the boards, or other functions or combination of these and/or other functions. The controller 132 and/or other device can also send signals to other devices such as a processor, other hardware, software or firmware to perform those functions. While the controller or detector 132 or other device connected to the arrows at the end of lines 128 and 130 has been described as potentially being a controller, a detector, a chipset, or a detection mechanism, for example, that device could be any number of other hardware, software, firmware or other devices or combination of such devices according to some embodiments. For example, in some embodiments the controller 132 can be a combination of hardware devices (for example, a controller or a detector combined with firmware and/or with software). In some embodiments the controller 132 may be a controller or detector implemented entirely in software or in firmware. Additionally according to some embodiments the controller/detector 132 and/or other device could be included in, on, near or attached to one of the boards 102 or 104, or according to some embodiments could be in some other place not in, on, near or attached to those boards.

In some embodiments controller 132 may be a device that can detect the connection and lack of connection of the protection circuit, remove power from the system and/or one or more of the boards and/or perform other functions as described herein in reference to controller 132 or to other detectors, controllers or implementations such as firmware implementations. In some embodiments controller 132 can be one or more devices that include a detector that can detect a connection, lack of connection and/or open circuit condition of a protection circuit and other functions as described herein, and can also include a separate controller that can remove power from being supplied to the system and/or to one or more of the boards, and/or other functions as described herein in reference to a detector or controller (for example, a function of logging events and other functions).

In some embodiments, an event such as a tampering event (for example, disassembly of an adapter card) may be detected even if no AC power is provided to a system (for example, because the system is unplugged). When the event is detected it is possible to stop the system from booting, thus discouraging any sort of tampering event by rendering the system useless and making it impossible to steal content by probing the system, for example.

In some embodiments the connector between the boards (for example, between an adapter board and a baseboard) will form a circuit. This circuit may be connected to a detection mechanism or similar inputs of a chipset or other devices that remain operative when the system is off or in a “sleep mode” or some other mode where the system is powered by a system battery, for example. Once a correct adapter has been installed and mated to the baseboard the protection circuit can be polled, monitored or checked in some other way to determine whether an event such as a tampering event has occurred and responses may be made to deal with the issue. For example, protection circuitry, hardware, software, firmware and/or some other device may be used to log an event, set a register bit in the permanent memory space (e.g., EEPROM), provide an alert, shutdown the system and prevent further operation, and/or perform some other response or combination of responses.

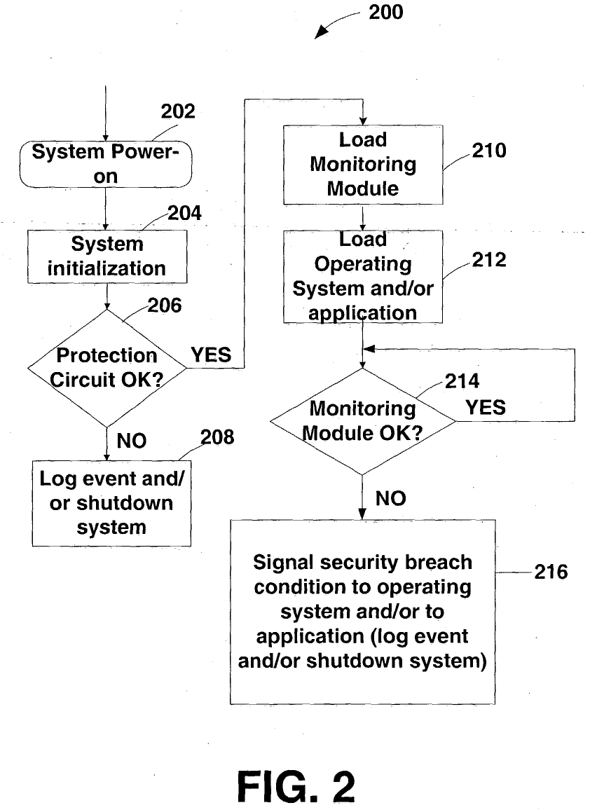

FIG. 2 illustrates a flow diagram including a flow 200 according to some embodiments. The flow 200 could be implemented in hardware, software, firmware. or in some other manner according to some embodiments. The embodiments illustrated in FIG. 2 need not be limited to being performed by particular hardware, software, firmware or any particular components or devices, and need not perform exactly the same flow as illustrated in FIG. 200. Many variations of the flow illustrated in FIG. 2 may be implemented according to some embodiments. In some embodiments the flow illustrated in FIG. 2 can be implemented using any of the detectors and/or controller described in reference to FIG. 1, or using any other detectors, controllers or other devices according to some embodiments, whether implemented in hardware, software, firmware and/or any other implementation or combination of implementations.

According to some embodiments a system power-on event occurs at 202 of flow 200. System initialization (for example, firmware system initialization) occurs at 204. At 206 a determination is made as to whether or not a protection circuit is OK (and/or whether circuit protection is OK). The protection circuit may be the protection circuit illustrated in FIG. 1 or some other protection circuit or content protection circuit or circuit protection. According to some embodiments in order to determine whether or not the protection circuit is OK the determination at 206 might identify if an open circuit has occurred or is occurring in the protection circuit. If the protection circuit is not OK at 206 then an event may be logged and/or the system may be immediately shut down at 208 in a manner that prevents further operation of the system.

If a determination is made at 206 that the protection circuit is OK, then a monitoring module such as a run-time content protection (CP) monitoring module is loaded at 210. In some embodiments the loaded monitoring module may be a circuit protection software monitoring module. The system loads an operating system and/or an application at 212. A determination is made at 214 as to whether the monitoring module is OK (and/or whether the protection circuit and/or circuit protection is OK). In some embodiments the monitoring module may be a run-time content protection (CP) monitoring module. In some embodiments the determination at 214 may be made using hardware, circuitry, software, firmware and/or some other device or combination thereof to monitor a protection circuit (for example, using a polling implementation). In some embodiments the determination at 214 may be made by an alert implementation using a wake-up interrupt mechanism (for example, in a chipset or some other circuitry, hardware, software firmware, etc.)

If a determination is made at 214 that a monitoring module is not OK (for example, due to an open circuit of a protection circuit identifying an event such as a tampering event, for example) then a security breach condition is signaled to the operating system and/or an application at 216. In some embodiments an event is logged and/or the system is shut down at 216. In some embodiments upper layer software is signaled at 216 to log an event and shutdown the system. The upper layer software may be, for example, operating system or application software. Alternatively, the signal may be provided to other software, to firmware, to hardware or to some other circuitry that can log an event and shutdown the system.

In some embodiments firmware may be used to monitor a protection circuit (for example, a content protection circuit). System firmware code may be loaded from non-volatile memory. A firmware initialization process may then check the battery condition and the status of a content protection circuit. If no fault is found during the power-up initialization process, the firmware may install a run-time module, which can alert upper-layer software (for example, an operating system or an application) in the event that the protection circuit is interrupted.

In some embodiments firmware constantly monitors the protection circuit hardware (for example, using polls) and/or is alerted through a wake-up interrupt mechanism in the chipset (or similar circuitry). In some embodiments, when the firmware detects that the protection circuit is broken (the system is compromised), the firmware can:

Immediately shutdown the system, and prevent further operation, if detected during power-up of the system; and/or

Alert the upper-layer software (such as an operating system or application) that the system has been compromised and that it should alert and/or log this event, and then shutdown the system.

According to some embodiments a hardware register (e.g., in the non-volatile memory space) may be used which can log a battery “low power” (failure) event. This could happen if the battery has failed or has been removed or replaced. If this condition exists, the firmware will treat this as a tampering event (for example, of an add-in card) and the software will not allow the system to boot.

In some embodiments software and/or firmware checks whether or not a battery is good. The battery can be any battery, and can be a battery that is already used for other purposes such as a battery included with a chipset, for example. Then a check can be made to ensure that no trigger event due to tampering with the system has occurred. If tampering has occurred the system can be set up so that it will not even boot up. This can be accomplished by using the small amount of power afforded by the battery to detect if one board such as an adapter is disconnected from another board. The battery detects an open circuit event associated with the disconnection, and can then be used to keep the system from operating. In some embodiments a system reset can be performed using a special utility, for example, if the system is sent back to the factory for special servicing or is serviced by a valid technician so that disconnect events can be performed by authorized personnel without completely and permanently deactivating the system due to a disconnect event.

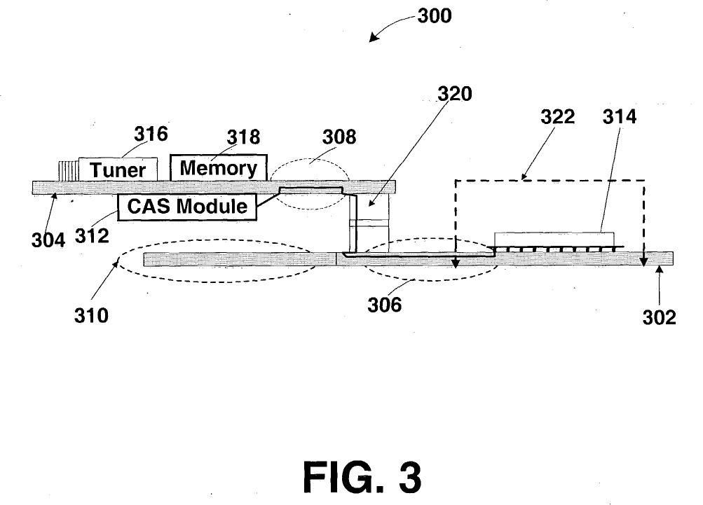

FIG. 3 illustrates a system 300 including a first board 302 and a second board 304. In some embodiments system 300 may be a consumer convergence system, a multimedia convergence system, and/or some other type of system. In some embodiments first board 302 may be a Printed Circuit Board (PCB), a motherboard, a baseboard and/or some other type of board. In some embodiments second board 304 may be a device, a module, a component, hardware, a PCB, a card, an adapter board, an adapter card, an add-in board, an add-in card, some other type of board, and/or some other type of card.In some embodiments board 302 can include inner layer signal traces generally shown within dotted lines 306. In some embodiments board 304 can include inner layer signal traces generally shown within dotted lines 308. Inner layer signal traces such as traces 306 and/or 308 may be routed within boards 302 and/or 304, respectively, in order to prevent signal probing. In order to attempt to probe an inner layer signal trace one might attempt to drill open the board in which the inner layer signal trace is routed. However, such an attempt to drill open a board in such a manner would damage the trace and potentially ruin the board and/or the entire system.

In some embodiments board 302 can include an overlap portion generally shown within dotted line 310. Even when inner layer signal traces are routed within a board those traces typically have to come to a surface of the board at some point. The signal trace that comes to the bottom portion of board 304 at the bottom left of inner layer signal trace 308 is connected to a Conditional Access System (CAS) Module 312. In some embodiments that signal trace is connected to some other circuitry or module. Conditional Access System (CAS) Module 312 can be used on a board in a convergence consumer product, for example. Overlap portion 310 of board 302 is used to help prevent signal probing on the trace between inner layer signal trace 308 and board 304. In some embodiments overlap portions of boards can be used to help prevent signal probing of other traces near the surface of another board, and need not be near a CAS Module, a board and/or it's mating connector, or any particular location or chip on the board. For example, overlap portion 310 could be used to help prevent signal probing near another device on the bottom of board 304 such as a tuner, a ROM or some other device or chip on board 304. Similarly board 304 could be extended with an additional overlap portion (not shown in FIG. 3) that helps prevent probing of surface traces near devices (or not near devices) on board 302.

In some embodiments chips that are difficult to probe leads out of those chips may be used on either or both of boards 302 and 304. For example, a chip 314 on board 302 may have a ball grid array (BGA) type chip package which is difficult to probe since signals come in and out of the BGA chip through solder balls at the bottom of the chip. Other chips may have packages other than BGA packages according to some embodiments. For example, other packages that may be used according to some embodiments include Flip Chip Ball Grid Array (FCBGA) or other packages. Additionally, it is noted that any or all components on boards 302 and/or 304 can include packages that are difficult to probe according to some embodiments, although such packages are not specifically illustrated in FIG. 3. In some embodiments chip 314 can be a processor, a video chip, a graphics chip, a video/graphics chip, an MPEG decoder, a signal processing chip, and/or any type of integrated circuit.

In some embodiments, in addition to the Conditional Access System Module 312, board 304 can also have a tuner 316 to receive information (for example, data, multimedia content or some other type of information) attached thereto. In some embodiments instead of (or even in addition to) tuner 316 board 304 can have a 1394 input, a DVI input/output or other types of inputs and/or outputs. Board 304 can also have a memory device such as a Read Only Memory (ROM) 318 attached thereto. In some embodiments memory 318 can be a Read Only Memory (ROM), a Programmable Read Only Memory (PROM), an Electrically Erasable Programmable Read Only Memory (EEPROM) and/or some other type of memory. In some embodiments memory 318 can be used to store a unique ID that identifies board 304 and/or board 302 (for example, a board ID number or an adapter ID number). In some embodiments a unique ID identifying board 304 and/or board 302 may be stored in the Conditional Access System Module 312. In some embodiments the unique ID can also be embedded or stored in other components. The unique ID may be used to ensure that board 304 and board 302 will only function when connected with each other. That is another board may not be connected with 302 and function as intended. In this manner a hacker is not able to pull board 304 away from board 302 and connect a new board such as a different adapter board to board 302 or a different baseboard to board 304 to get the system to operate.

In some embodiments a board 304 is an adapter board or an adapter card that has a number that is matched with only one board 302 such as a baseboard. The two boards 302 and 304 are married and will not work when connected to other boards. In some embodiments a unique identifier can be anywhere on the board 304 or board 302 or on any component attached to either board. An identifier identifying board 304 could be stored, for example, in memory 318 or CA module 312 or in any other component on board 304. The component in which the identifier is stored need not be a standalone memory device such as memory 318, and memory 318 of FIG. 3 need not be a standalone memory device as described. Memory 318 could be a standalone memory device or any other device in which an identifier could be stored.

In some embodiments board 302 and board 304 are connected using a connector 320. Connector 320 can be a Surface Mount Connector (SMT) or any other type of connector. A Surface Mount Connector is beneficial because it is more difficult to probe than some other connectors. For example, some through-hole pin connectors are easy to probe because a pin goes through to the far surface of a board to which it is connected. On the other hand Surface Mount Connectors do not have pins or traces that go through to a far end surface of either of the boards 302 and 304. Connectors that may be used to enhance prevention of probing between boards include Surface Mount Connectors or any other type of connector that helps prevent or hinder someone probing signals at a connection point between boards.

In some embodiments a metal can and/or a metal frame may be used to enclose one or more of the components on either of the boards being connected. This may be implemented, for example, on any of the components on board 302 or on board 304, including but not limited to chip 314, Conditional Access Module 312, Memory 318 and/or Tuner 316. A metal can 322 is illustrated as a dotted line in FIG. 3 surrounding chip 314. The metal can 322 can surround chip 314 entirely or partially, and can also be a metal frame in some embodiments. Metal can 314 provides additional security by surrounding chip 314 in order to enclose it and prevent attempts to probe any leads or solder balls extending from chip 314. Attempts to remove metal can 322 generally can cause irreparable damage to chip 314 and/or to board 302. In some embodiments metal can 322 is entirely enclosed with tops and sides so that no access can be made to any component between that can and the board. In some embodiments can 322 does not have a top or does not have one or more sides or can be a frame but prevents probe access to any component underneath.

A variety of ways to prevent probing of certain signals have been described herein according to some embodiments, including a protection circuit connection between two boards, detection of an open circuit in a protection circuit, software and/or firmware to make the system unbootable, inner signal trace routing, board overlapping, use of protective chip packaging, storing of a unique identifier identifying a board, special connector to prevent probing such as an SMT connector and a metal can or metal frame covering one or more component on one or more connected boards. However, many embodiments are possible using one or more of these techniques. Not all of these techniques are necessary according to some embodiments. In many embodiments any one or more of these techniques may be implemented to prevent tampering and/or probing of the system.

In some embodiments a flexibility of configuration is provided, for example, because the same baseboard can be used to support various adapters with different tuner types and Conditional Access Schemes (CAS). This is particularly beneficial in view of, for example, proprietary CAS schemes in the United States cable market segment. In some embodiments some level of the key exchange between the adapter and the baseboard is eliminated because it is not necessary to encrypt and/or decrypt content prior to sending it across the connector between the adapter and the baseboard. This can simplify the design process such as the software design process and can enhance the time to market (TTM) of the product.

In some embodiments a lower system cost is possible because decrypted content from the CAS does not need to be re-encrypted. This reduced level of data handling will lower the hardware and software implementation work and cost of the system. In some embodiments the hardware system design is simplified because the same baseboard can be re-used and only a new adapter need be designed for different markets, market segments and/or geographies. If a common flexible baseline platform can be used for market segments such as convergence consumer products in a manner similar to the ATX form factor for desktop computers then costs can be minimized and different companies can provide different product differentiations using different add-in cards/adapters/boards, etc.

In some embodiments the content is protected so that a hacker cannot probe decrypted content. In some embodiments firmware can stop the system from booting when a board set has been tampered with. This tampering event can be detected even when AC power to the unit has been disconnected. In some embodiments no resource for re-encrypting content is necessary. This allows for a lower overall system cost both in terms of hardware and software.

Some embodiments have been described and illustrated herein as being capable of being implemented in convergence consumer products such as multimedia convergence products. However, the inventions are not limited to convergence consumer products or multimedia convergence products, and the embodiments described, illustrated and/or claimed herein should not be limited solely to such products. Some embodiments could be implemented where any board, card, etc. is connected to another board, card, etc. (for example, an add-in card to be connected to a motherboard in a computer system).

In each system shown in a figure, the elements such as boards, connectors and connector pins, for example, in some cases each have a different reference number to suggest that the elements represented could be different. However, an element may be flexible enough to have different implementations and work with some or all of the systems shown or described herein. The various elements shown in the figures may be the same or different. Which one is referred to as a first element and which is called a second element is arbitrary.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances “an embodiment,” “one embodiment,” or “some embodiments” are not necessarily all referring to the same embodiments.

If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

Although flow diagrams may have been used herein to describe embodiments, the inventions are not limited to those diagrams or to corresponding descriptions herein. For example, flow need not move through each illustrated box or exactly in the same order as illustrated and described herein.

The inventions are not restricted to the particular details listed herein. Indeed, those skilled in the art having the benefit of this disclosure will appreciate that many other variations from the foregoing description and drawings may be made within the scope of the present inventions. Accordingly, it is the following claims including any amendments thereto that define the scope of the inventions.

What is claimed is:

1. An apparatus comprising:
a controller to detect a board coupling condition and to perform a shutdown in response to the board coupling condition.

2. The apparatus as claimed in claim 1, wherein at least a portion of the controller is attached to a board.

3. The apparatus as claimed in claim 1, wherein the board coupling condition is a coupling condition of a board and a device.

4. The apparatus as claimed in claim 3, wherein the device is a second board.

5. The apparatus as claimed in claim 4, wherein the second board is an adapter card.

6. The apparatus as claimed in claim 4, wherein the second board is an add-in card.

7. The apparatus as claimed in claim 4, further comprising a connector to couple the board to the second board.

8. The apparatus as claimed in claim 3, wherein the board is a printed circuit board.

9. The apparatus as claimed in claim 1, wherein the board coupling condition is a coupling condition that occurs when no AC power is being supplied.

10. The apparatus as claimed in claim 1, wherein the shutdown is a shut down of a system.

11. The apparatus as claimed in claim 3, wherein the shutdown is a removal of power from at least one of the board and the device.

12. The apparatus as claimed in claim 1, the controller further to log an event in response to the board coupling condition.

13. An apparatus comprising:
a detector to detect a board coupling condition; and
a controller to perform a power shutdown in response to the board coupling condition.

14. The apparatus as claimed in claim 13, wherein the board coupling condition is a coupling condition between a board and a device when AC power is not being supplied to either the board or the device.

15. The apparatus as claimed in claim 13, wherein the controller is further to shut down a system in response to the board coupling condition.

16. The apparatus as claimed in claim 14, wherein the device is at least one of a board, an add-in card, an adapter card, and a module.

17. A system comprising:
a board;
a device;
a connector to couple the board to the device;
an electrical circuit formed among the board, the connector and the device; and
a controller to perform a shutdown of the system in response to the electrical circuit.

18. The system as claimed in claim 17, further comprising a detector to detect an open circuit condition of the electrical circuit, the controller to perform the shutdown in response to the open circuit condition.

19. The system as claimed in claim 17, wherein the device is at least one of a board, an add-in card, an adapter card and a module.

20. The system as claimed in claim 17, wherein the device is a second board and at least one of the board and the second board is a printed circuit board.

21. The system as claimed in claim 17, wherein the device is a second board and at least one of the board and the second board is an adapter card.

22. The system as claimed in claim 17, wherein the device is a second board and at least one of the board and the second board is an add-in card.

23. The system as claimed in claim 17, wherein the device is a second board and at least a portion of the controller is attached to at least one of the board and the second board.

24. The system as claimed in claim 17, the controller to detect an uncoupling of the board and the device in response to the electrical circuit, and to perform the shutdown in response to the uncoupling.

25. The system as claimed in claim 17, the controller to perform the shutdown by ensuring that power is not supplied to at least one of the first board and the device.

26. The system as claimed in claim 17, wherein the controller is a detector.

27. The system as claimed in claim 17, further comprising a detector to detect an uncoupling of the board and the device, the controller to perform the shutdown in response to the uncoupling.

28. The system as claimed in claim 17, the controller to perform the shutdown in response to an uncoupling of the board and the device.

29. The system as claimed in claim 28, wherein the uncoupling is an uncoupling of the board and the device when AC power is not being supplied to either the board or the device.

30. The system as claimed in claim 17, wherein the device is a second board and at least one of the first board and the second board includes inner layer trace signals.

31. The system as claimed in claim 17, wherein the device is a second board and at least one of the board and the second board overlaps the other board in a portion of the other board near the connector.

32. The system as claimed in claim 17, wherein the device is a second board and at least one of the board and the second board includes a component having a package that is difficult to probe.

33. The system as claimed in claim 32, wherein the package is at least one of a ball grid array package and a flip chip ball grid array package.

34. The system as claimed in claim 17, wherein the board includes a component having a package that is difficult to probe.

35. The system as claimed in claim 34, wherein the package is at least one of a ball grid array package and a flip chip ball grid array package.

36. The system as claimed in claim 17, wherein the device is a second board and at least one of the board and the second board has attached thereon a memory device to store a unique identifier identifying at least one of the board and the second board.

37. The system as claimed in claim 36, wherein the board has attached thereon a first memory device to store a unique identifier identifying at least one of the board and the second board and wherein the second board has attached thereon a second memory device to store a unique identifier identifying at least one of the board and the second board.

38. The system as claimed in claim 17, wherein the board has attached thereon a memory device to store a unique identifier identifying at least one of the board and the second board.

39. The system as claimed in claim 17, wherein the connector is a connector that is difficult to probe.

40. The system as claimed in claim 39, wherein the connector is a surface mount connector.

41. The system as claimed in claim 17, further comprising a metal can enclosing at least one component attached to the board.

42. The system as claimed in claim 17, wherein the device is a second board and further comprising a metal can enclosing at least one component attached to the second board.

43. The system as claimed in claim 17, wherein the controller performs the shutdown in response to an open circuit condition of the electrical circuit.

44. A method comprising:
monitoring a board coupling condition; and
performing a shutdown in response to the monitoring.

45. A method as claimed in claim 44, wherein the shutdown includes ensuring power is not supplied to a board.

46. The method as claimed in claim 44, wherein the board coupling condition is a coupling condition between a board and a device when AC power is not being supplied to either the board or the device.

47. The method as claimed in claim 44, wherein the board coupling condition corresponds to a condition of a protection circuit between a board and a device.

48. The method as claimed in claim 44, wherein the shutdown includes shutting down a system.

49. The method as claimed in claim 48, wherein the shutdown includes shutting down the system immediately upon detection of the board coupling condition during a power-up.

50. The method as claimed in claim 44, wherein the shutdown includes providing at least one of an alert and a log event.

51. An article comprising:
a computer readable medium having instructions thereon which when executed cause a computer to:
monitor a board coupling condition; and
perform a shutdown in response to the board coupling condition.

52. The medium as claimed in claim 51, wherein the shutdown includes shutting down a system.

53. The medium as claimed in claim 51, wherein the board coupling condition is a condition occurring when no AC power is being supplied.
